(19) United States
(12) Patent Application Publication
(10) Pub. No.: US 2010/0058274 A1
(43) Pub. Date: Mar. 4, 2010

(54) FLEXIBLE HARDWARE UPGRADE MECHANISM FOR DATA COMMUNICATIONS EQUIPMENT

(75) Inventors: Dion PIKE, Stittsville (CA); David Peppy, Ottawa (CA); John Madsen, Austin, TX (US)

Correspondence Address: Kramer & Amado, P.C., 1725 Duke Street, Suite 240, Alexandria, VA, 22314, US

(73) Assignee: ALCATEL LUCENT, Paris (FR)

(21) Appl. No.: 12/204,569

(22) Filed: Sep. 4, 2008

(51) Int. Cl. G06F 17/50; H03K 19/173

(52) U.S. Cl. 716/16; 326/37

(57) ABSTRACT

Partial reconfiguration of programmable logic devices may be achieved in a hardware-controlled manner without relying upon software. Upon installation of a new memory module, partial reconfiguration may enable alteration of a clock frequency without affecting operation of the software. When a new interface is installed, partial reconfiguration will allow a programmable logic device to adapt to either a serial or parallel interface before executing a standard boot-up sequence for the computer system.

### BACKGROUND OF THE INVENTION

1. Field of the Invention

This invention relates generally to hardware configuration for routers.

2. Description of Related Art

Router systems are computer components that include both hardware and software elements. By means of this hardware and software, routers select paths in a computer network and forward information along the selected path. Particular software loads can be used to designate a frequently used pattern of paths for forwarding data.

Many customers of data communications equipment standardize on a particular software load and become hesitant to move away from this load. This can present a problem when new or upgraded hardware is introduced to a router system that requires programmable logic devices, such as Field Programmable Gate Arrays (FPGAs), to be programmed differently. If the software load is responsible for programming the FPGA, then clearly new hardware implies new software is necessary and customers may be hesitant to perform such an upgrade.

An FPGA is a semiconductor device containing programmable logic components called “logic blocks”, and programmable interconnects. A customer or designer can program the logic blocks and interconnects after the FPGA is manufactured to implement logical functions. In contrast, Application-Specific Integrated Circuits (ASICs) cannot be programmed in this manner.

FPGAs were first invented by Ross Freeman, a co-founder of Xilinx, in 1984. Early FPGAs used a logic block consisting of a 4-input Look-Up Table (LUT) and a flip flop, but FPGAs today often used 6-input LUTs. Newer versions of FPGAs can be reprogrammed at run time, permitting computers to be rapidly altered to become more suitable for a particular task.

Customers of data communications equipment often complain that systems take too long to stablilize when initially turned on, particularly in a case where an element of the hardware, such as an FPGA, must be upgraded to a new version of its program. During boot-up, the FPGA can be first programmed with a default, static version of its software. Then, the software will detect that the FPGA code version is out-of-date and download the new code to the FPGA, adding a dynamic version of the software. Finally, the software initiates reset so that the hardware is in a well-defined state before the system becomes operational. This additional reset effectively doubles the hardware boot-up time and may be a concern for many customers.

FPGAs having configurable data path transceivers are currently available. Although these transceivers could be configured to support different interface speeds between multiple I/O cards and a single line processing card, transceiver configurations for all transceivers are normally dependent upon a specific FPGA software load. Thus, changing the speed of one transceiver typically requires a completely new software load. The entire FPGA, including transceivers whose configurations are not being adjusted, must be reset to initialize the new software. Consequently, all data path transfers involving the FPGA must be interrupted when the speed of only one of the FPGA transceivers is changed. Thus, there is a need to upgrade software on an FPGA without shutting down all data path transfers in the router system.

For more efficient router systems, partial reconfiguration is a design process that allows a limited, predefined portion of a FPGA to be reconfigured while the remainder of the device continues to operate. Partial reconfigurability permits logic to be changed or updated within part of a FPGA without disrupting the entire system. Xilinx has recently developed FPGAs that are capable of such partial reconfiguration.

Partial reconfiguration may provide numerous benefits. A user may adapt hardware algorithms, share hardware between various applications, increase resource utilization, provide continuous hardware servicing, and remotely upgrade hardware. Such benefits may be obtained from either module-based or difference-based partial reconfiguration.

Module-based partial reconfiguration uses reconfigurable modules with a FPGA. Because the specific properties and layout must be predefined, any FPGA that uses this type of partial reconfiguration must be carefully designed to meet these criteria. Otherwise, the partial reconfiguration process will not occur properly.

At least three steps are involved in traditional module-based partial reconfiguration. First, areas must be assigned to at least one Partial Reconfiguration Module (PRM) using a range of physical blocks, defined within the overall fabric of the FPGA by a proper PRM attribute. Second, static logic must be established that groups all other top-level modules into a static logic block. Third, bus macros should be placed to properly handle the PRM and static logic block.

Difference-based partial reconfiguration involves small changes in either the front end or the back end of the FPGA. The differences may include altered Input/Output (I/O) standards, Look-Up Table (LUT) equations, and block Random Access Memory (RAM) content. Front end changes can be schematic or done with Hardware Description Language (HDL). Back end modifications may be made by a FPGA Editor or a Graphical User Interface (GUI).

The emergence of new FPGA families such as the Xilinx 6200 FPGA family and the Atmel 40000 series has been an important development in the FPGAs. These devices have number of appealing features when compared to older technologies such as faster reconfiguration (typically μs), support for partial reconfiguration, and use of a dedicated microprocessor interface. An approach for run-time reconfiguration can be achieved by considering a range of functions collectively and developing the specific circuit architectures for each so that a high degree of commonality exists between them in terms of their structure, wiring, and cell function. Virtual hardware may be integrated within the operating system. In such cases, the reconfigurable designs which allow partial reconfiguration of the FPGAs are stored within a configuration data graph.

Partial reconfiguration offers countless benefits across multiple industries by providing the ability to reconfigure selected areas of an FPGA anytime after its initial configuration. Active partial reconfiguration occurs when the design is operational and the device is active, while static partial reconfiguration occurs when the device is inactive in shutdown mode. In either case, partial reconfiguration can adapt hardware algorithms, share hardware between various applications, increase resource utilization, provide continuous hardware servicing, and upgrade hardware remotely rather than requiring local installation of hardware.

In general, there is a need to provide partial reconfiguration of FPGAs remotely without imposing a software upgrade upon customers. These customers may be unhappy if required to accept new software as part of an FPGA upgrade because they have become acclimated to a particular software load. Also, new software could destabilize an existing system.

In some systems, the FPGA is first programmed with a default version. Software then detects that the version of the FPGA is outdated and responds by downloading new code. The software also resets the system so that the FPGA is configured to a well-defined state before the system becomes fully operational. This technique is quite inefficient because it effectively doubles the hardware bootup time. Thus, there is a need to reduce this burden on customers by updating a FPGA in a hardware-controlled manner, avoiding such use of software.

### SUMMARY OF THE INVENTION

In light of the present need for hardware-controlled reconfiguration of programmable logic devices, a brief summary of various exemplary embodiments is presented. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

In various exemplary embodiments, a hardware-controlled mechanism that reconfigures programmable logic devices may comprise: a line card comprising a memory coupled to a programmable logic device and a microprocessor, the microprocessor coupled to the programmable logic device and the memory, and the programmable logic device coupled to the memory, the microprocessor, and the input; the input providing a program for partial reconfiguration of the programmable logic device. The programmable logic device may be a Field Programmable Gate Array (FPGA).

In various exemplary embodiments, a method of upgrading a programmable logic device may comprise the following steps: programming the programmable logic device with a test program; determining a version of hardware; obtaining a configuration file that corresponds to the determined version; programming the programmable logic device with the configuration file; and carrying out a boot-up sequence after the programming step is complete. The programmable logic device may be a Field Programmable Gate Array (FPGA).

In various exemplary embodiments, a method of upgrading a programmable logic device may comprise the following steps: performing a boot-up sequence for a computer system; interrupting the boot-up sequence; detecting characteristics of a newly installed upgrade; retrieving a configuration file that corresponds to the detected characteristics; configuring the programmable logic device with the configuration file; and resuming the boot-up sequence after the configuring step is complete. The programmable logic device may be a Field Programmable Gate Array (FPGA).

In various exemplary embodiments, the newly installed upgrade may be a memory module. In that case, the configuring step may change the frequency of a reference clock. This frequency may be selected to optimize a system performance level based upon a thermal constraint. The memory module may be a Dual Inline Memory Module (DIMM). The configuring step may occur while a processor that uses the reference clock is in a reset mode.

In various exemplary embodiments, the newly installed upgrade may be an interface. In that case, the configuring step may adapt the programmable logic device to the interface, depending upon whether the interface is serial or parallel.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the preceding disclosure, description, and figures are for illustrative purposes only and do not in any way limit the invention, which is defined only by the claims.

### BRIEF DESCRIPTION OF THE DRAWINGS

In order to better understand various exemplary embodiments, reference is made to the accompanying drawings, wherein:

FIG. 1 depicts a line card for a routing system that is coupled to an input;

FIG. 2 depicts a system for partial reconfiguration of a programmable logic device;

FIG. 3 depicts a first exemplary method of partial reconfiguration;

FIG. 4 depicts a second exemplary method of partial reconfiguration; and

FIG. 5 depicts a third exemplary method of partial reconfiguration.

### DETAILED DESCRIPTION OF THE PREFERRED EMBODIMENTS OF THE INVENTION

Referring now to the drawings, in which like numerals refer to like components or steps, there are disclosed broad aspects of various exemplary embodiments.

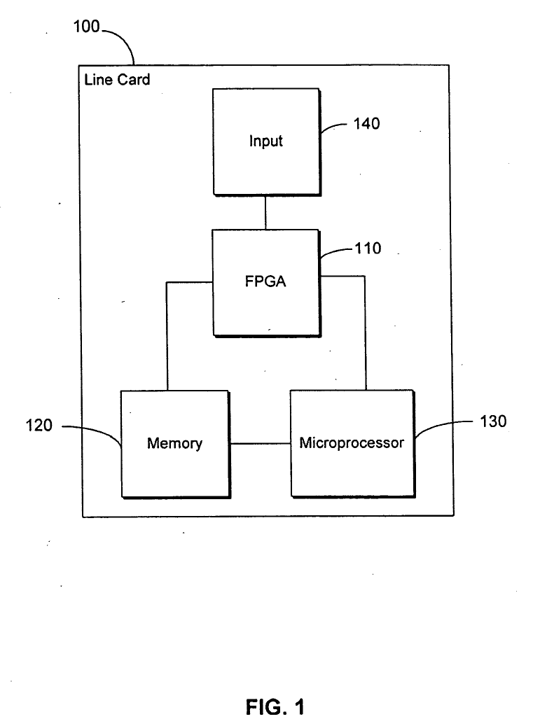

FIG. 1 depicts a line card 100. In various exemplary embodiments, a line card 100 comprises a programmable logic device 110, a memory 120, and a microprocessor 130, and an input 140.

Programmable logic device 110 maybe a Field Programmable Gate Array (FPGA). This FPGA may be implemented by flip flops, such as data flip flops (DFFs). Device 110 is coupled to memory 120, microprocessor 130, and input 140. Memory 120, used for temporary storage of data, is coupled to device 110 and microprocessor 130. Microprocessor 130 is coupled to device 110, thereby allowing microprocessor 130 to process programs, and to memory 120, permitting microprocessor 130 to both load and store data. Input 140 permits partial reconfiguration of device 110, as described in more detail below. Input 140 may be located on line card 100 or connected to line card 100 from some other source.

By using configuration files received from input 140, line card 100 adapts hardware in data communications equipment to specific customer requirements, such as cost, performance, and physical constraints, in cases where system software is not capable of carrying out the configuration. In most cases, this is due to the simple fact that the act of reconfiguration causes instability in the system software. For example, a customer may choose to operate a processor at some clock frequency to optimize performance versus thermal constraints, but the software that executes on this processor cannot change the clock frequency without affecting proper operation of the software itself. Instead, it is beneficial to use a hardware-controlled mechanism that ensures that the hardware reconfiguration process remains transparent to any software already on the system.

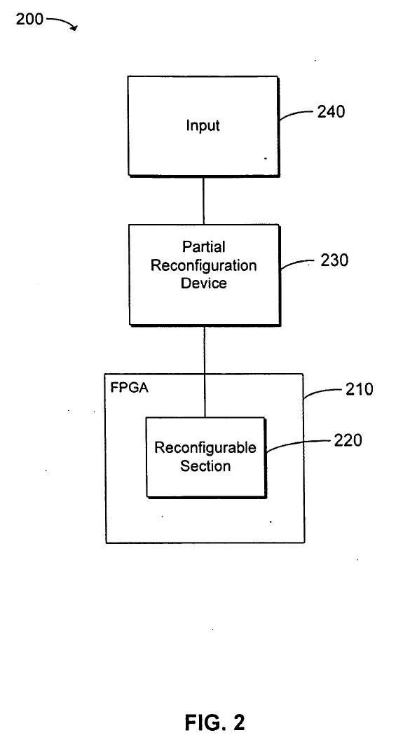

FIG. 2 depicts a system 200 for partial reconfiguration of programmable logic device 210. In various exemplary embodiments, system 200 includes a programmable logic device including a reconfigurable section 220, a partial reconfiguration device 230, and an input 240.

Programmable logic device 210 may be a Field Programmable Gate Array (FPGA) and may include a reconfigurable section 220. Reconfiguration section 220 is coupled to partial reconfiguration device 230 and allows reconfiguration of a portion of programmable logic device 210. Input 240 provides data to partial reconfiguration device 230 that can be applied to the reconfigurable section 220 of programmable logic device 210. Input 240, like input 140 of FIG. 1, may be located on the same line card as programmable logic device 210 or may be placed in a source external to the line card.

Regarding the operation of partial reconfiguration device 230, this mechanism upgrades a programmable logic device 210, such as a Field Programmable Gate Array (FPGA), in data communications equipment in a manner that is transparent to system software. In addition, the operation of device 230 is, to a large extent, transparent to customers. Newer FPGAs, such as the Virtex™ family from Xilinx, are capable of partial reconfiguration, wherein portions of a device can be programmed without affecting proper operation of the remainder of the device.

By means of device 230, this feature can be used to implement a transparent hardware upgrade. At boot-up, the programmable logic device 210 is programmed with a simple load that determines which version of the operational program is required to properly configure the routing system. It then executes that test program, causing partial reconfiguration of the dynamic portion of programmable logic device 210. In this way, no customer-visible software is changed and the duration of the upgrade is minimized.

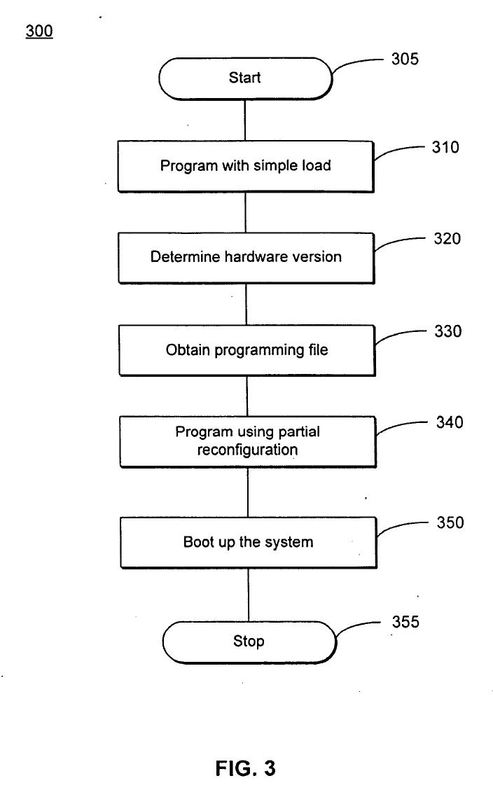

FIG. 3 depicts a first exemplary method 300 of partial reconfiguration.

Method 300 starts at step 305. First, in step 310, the system programs the logic device with a static load that is never intended to be upgraded. This load may be used to determine whether an upgrade is necessary upon boot-up of the system. Next, in step 320, the test program determines the current hardware version, possibly by reading the state of certain hardware version inputs.

Hardware can adapt to a configurable aspect of the hardware by detecting the status of the configurable aspect and then setting up the hardware appropriately. For example, when a user of some hardware element has the option of installing memory modules of different speed grades, a programmable logic device can be used during a boot-up sequence to detect the characteristics of the installed module and then configure the device to supply the appropriate reference clock. This partial reconfiguration is carried out with the majority of the routing system in reset mode.

Method 300 continues to step 330. Here, the routing system obtains an appropriate configuration file that may be recorded in external storage. In step 340, the dynamic portion of the FPGA is programmed with that configuration file using partial reconfiguration, while the static portion of the FPGA remains unchanged. Thus, the static portion of the FPGA can operate without interruption during the partial reconfiguration process. After partial reconfiguration is complete, a standard boot-up sequence occurs in step 350. Method 300 stops in step 355.

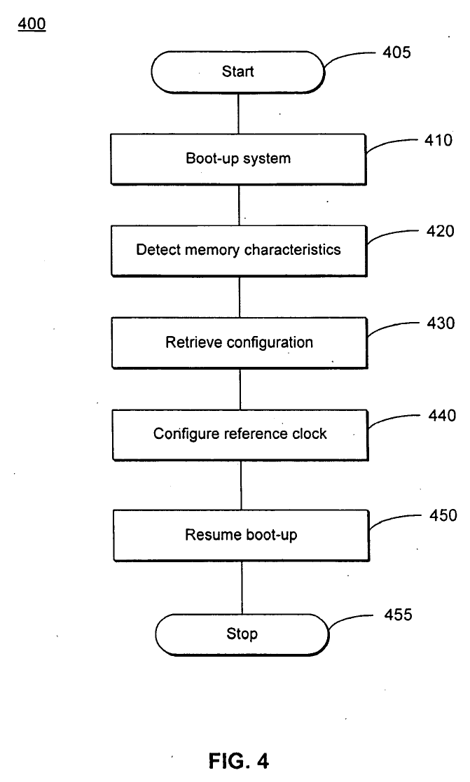

FIG. 4 depicts a second exemplary method 400 of partial reconfiguration.

Method 400 is particularly beneficial for router systems that use different clocks. A routing system may allow customers to use Dual Inline Memory Modules (DIMMs) of various speed grades. In particular, a faster DIMM may offer greater performance at the expense of additional cost, while a slower grade may be more suitable for lower cost systems or where thermal dissipation is a concern. Method 400 can adapt a routing system to a particular DIMM speed grade by reading the required information from the DIMM and modifying a reference clock accordingly.

A problem can occur if this modification is carried out under software control and that software is dependent on the reference clock, the same clock that sets the core clock of a processor. In this situation, a change in the clock could corrupt proper software execution. Thus, method 400 avoids this problem by having the hardware detect the DIMM speed grade and then use the detected information to modify the reference clock. Meanwhile, the processor that normally uses that clock is still in a reset mode, a mode in which no software is executing on that processor. Consequently, method 400 of FIG. 4 is quite advantageous as it changes the reference clock without requiring any control by software and thereby minimizes disruption of the overall system.

Method 400 starts at step 405. Initially, a normal system boot-up sequence is underway during step 410. This boot-up sequence is interrupted at step 420, as the system detects characteristics of a newly installed memory module.

Method 400 then continues to step 430. Here, the system obtains an appropriate configuration file that may be recorded in external storage. In step 440, a portion of the programmable logic device is programmed with that configuration file using partial reconfiguration, thereby configuring a reference clock for a Phase Locked Loop (PLL). Such configuration is necessary because memory modules have many different speed grades. Thus, the reference clock frequency must be appropriate for the installed memory. For example, the reference clock frequency may be selected to optimize a system performance level based upon thermal constraints in the system's environment. After partial reconfiguration is complete, the standard boot-up sequence resumes in step 450. Method 400 stops in step 455.

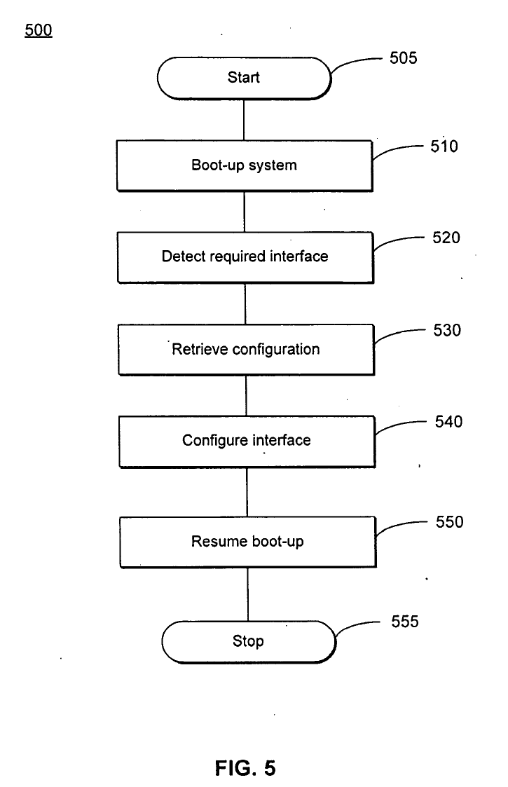

FIG. 5 depicts a third exemplary method 500 of partial reconfiguration.

Method 500 may permit two or more line cards to cooperate in a situation where each line card has a fundamentally different microprocessor. Method 500 starts at step 505. Initially, a normal system boot-up sequence is underway during step 510. This boot-up sequence is interrupted at step 520, as the system detects stored characteristics of a newly installed interface, which may be either serial or parallel.

Method 500 then continues to step 530. Here, the routing system obtains an appropriate configuration file that may be recorded in external storage. This configuration file will identify both the line card and its associated microprocessor.

In step 540, the dynamic portion of the programmable logic device is programmed with that configuration file using partial reconfiguration, thereby configuring the interface. If the programmable logic device is not properly adapted to the style of interface, serial or parallel, the interface will not be operational before the system software can boot. Thus, step 540 adapts the routing system to use an interface, such as a Peripheral Component Interface (PCI), that permits both line cards to be used. Alternatively, either a proprietary interface or an interface that one skill in the art would recognize as useful to couple both line cards could be used.

After partial reconfiguration is complete, the standard boot-up sequence resumes in step 550. This sequence should occur on all of the line cards. Method 500 stops in step 555.

According to the forgoing, various exemplary embodiments provide significant advantages. Various exemplary embodiments allow customers to tailor hardware to meet their specific needs and standardize on a software load without being constrained to a particular hardware version. Thus, various exemplary embodiments shorten system boot-up time when hardware, such as programmable logic devices, must be upgraded. Software will also be simplified because it is no longer involved in hardware configuration.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the preceding disclosure, description, and figures are for illustrative purposes only and do not in any way limit the invention, which is defined only by the claims.

What is claimed is:

1. A hardware-controlled mechanism that reconfigures programmable logic devices comprising:
a line card comprising:
a memory coupled to a programmable logic device and a microprocessor,
said microprocessor coupled to said programmable logic device and said memory, and
said programmable logic device coupled to said memory, said microprocessor, and an input,
said input providing a program for partial reconfiguration of said programmable logic device.

2. The mechanism of claim 1, wherein said programmable logic device is a Field Programmable Gate Array (FPGA).

3. The mechanism of claim 2, wherein said FPGA is implemented by flip flops.

4. The mechanism of claim 3, wherein said flip flops are data flip flops (DFFs).

5. A method of upgrading a programmable logic device comprising the following steps:
programming said programmable logic device with a test program;
determining a version of hardware for configuration of said programmable logic device by using said test program;
obtaining a configuration file that corresponds to said determined version;
programming said programmable logic device with said configuration file; and
carrying out a boot-up sequence after said programming step is complete.

6. The method of claim 5, wherein said programmable logic device is a Field Programmable Gate Array (FPGA).

7. The method of claim 6, wherein said FPGA is implemented by flip flops.

8. The method of claim 7, wherein said flip flops are data flip flops (DFFs).

9. A method of upgrading a programmable logic device comprising the following steps:
performing a boot-up sequence for a computer system;
interrupting said boot-up sequence;
detecting characteristics of a newly installed upgrade in the computer system;
retrieving a configuration file that corresponds to said detected characteristics;
configuring said programmable logic device with said configuration file; and
resuming said boot-up sequence after said configuring step is complete.

10. The method of claim 9, wherein said programmable logic device is a Field Programmable Gate Array (FPGA).

11. The method of claim 10, wherein said FPGA is implemented by flip flops.

12. The method of claim 11, wherein said flip flops are data flip flops (DFFs).

13. The method of claim 9, wherein said newly installed upgrade is a memory module.

14. The method of claim 13, wherein said configuring step changes the frequency of a reference clock.

15. The method of claim 13, wherein said frequency of a reference clock is selected to optimize a system performance level based upon a thermal constraint.

16. The method of claim 13, wherein said memory module is a Dual Inline Memory Module (DIMM).

17. The method of claim 13, wherein said configuring step occurs while a processor that uses said reference clock is in a reset mode.

18. The method of claim 9, wherein said newly installed upgrade is an interface.

19. The method of claim 18, wherein said configuring step adapts said programmable logic device to said interface, depending upon whether said interface is serial or parallel.

20. The method of claim 18, wherein said interface is a Peripheral Component Interface (PCI).
